(19) United States
(12) Patent Application Publication
(10) Pub. No.: US 2007/0065990 A1
(43) Pub. Date: Mar. 22, 2007

(54) Recursive spacer defined patterning

(76) Inventors: Bart Degroote, Delfgauw (NL); Rita Rooyackers, Kessel-Io (BE)

Correspondence Address: KNOBBE MARTENS OLSON & BEAR LLP, 2040 MAIN STREET, FOURTEENTH FLOOR, IRVINE, CA, 92614, US

(21) Appl. No.: 11/514,457

(22) Filed: Sep. 1, 2006

Related U.S. Application Data
(60) Provisional application No. 60/717,690, filed on Sep. 16, 2005.

(30) Foreign Application Priority Data
Dec. 19, 2005 (EP) EP 05447285.7

(51) Int. Cl. H01L 21/8232; H01L 21/84; H01L 21/335; H01L 21/00

(52) U.S. Cl. 438/142; 438/157

(57) ABSTRACT

A method for the patterning of a plurality of fins in a MugFET device is provided. The method involves depositing at least one temporary pattern using photolithography. Further processing steps include a combination of depositing a conformal layer and spacer defined patterning of the conformal layer such that a very high density of fins can be achieved. The distance between the fins is no longer determined by photolithography, which is only used to define the temporary pattern which is removed in further processing, but instead by the thickness of the conformal layer, with all fins defined by spacers. Additionally an improved line edge roughness is achieved for the fins using the method.

### CROSS-REFERENCE TO RELATED APPLICATIONS

This application claims the benefit of U.S. Provisional Application No. 60/717,690 filed Sep. 16, 2005, and European Application No. EP 05447285.7 filed on Dec. 19, 2005. Each of the aforementioned applications is incorporated by reference herein in its entirety, and each is hereby expressly made a part of this specification.

### FIELD OF THE INVENTION

A semiconductor processing method is provided that is of use in patterning of structures within a semiconductor device, and more specifically within multiple gate devices.

### BACKGROUND OF THE INVENTION

As the scaling of transistor dimensions in planar devices continues, short-channel effects become more of an issue.

MuGFET devices (multi-gate FET) can provide an answer to this problem. Due to their unique 3-D architecture with gates wrapped around a thin silicon fin, they show excellent gate control over the channel. The MuGFET's non-planarity however puts high demands on processing engineers and lithographers who have to deal with specific etching, implantation and patterning issues, as well as difficulties in tuning the threshold voltage.

The fin width needs to be in the sub-25 nm regime to achieve good suppression of short-channel effects. The narrower the fin, the better the gate control and the more robust the device is with respect to short-channel effects. A narrow fin, on the other hand, results in an increased source/drain resistance and can suffer more from line edge roughness, so a trade-off has to be made between very narrow fins to limit short-channel effects and wider fins to have a less source-drain resistance. The above-described architecture is that of a single-fin device. However, most of the time multiple-fin devices are used with several fins contacting large source/drain blocks to improve current drivability.

When using multiple fins in a finFET device, the fin density or in other words the distance between the fins is important.

U.S. Pat. No. 6,706,571 by Yu et al. discloses a method for forming a plurality (two) of fins in a finFET device by forming spacers on the sidewalls of a patterned trench and using these spacers to etch fins in the layer underneath. This method can result in narrow fins with less line edge roughness compared to resist based patterning (e.g. with 193 nm lithography). In the method from Yu et al., two fins are obtained starting from one lithographic pattern, therefore doubling the density of the lines. However, the distance between the individual fins is still determined by lithography.

### SUMMARY OF THE INVENTION

A method that further increases the fin density by keeping the fin distance as small as possible is desirable to obtain finFET devices with better performance.

The preferred embodiments provide a method for forming a mask for patterning a layer underneath, in the manufacture of a semiconductor device, specifically in the patterning of multiple fins to be used in a semiconductor device, and more specifically a MuGFET device.

A method according to the preferred embodiments can comprise the step of depositing over a patterned structure and etching back a conformal layer, such that the sidewalls of said patterned structure are used for forming a first generation of spacer-like structures (also referred to as spacers).

The patterned structure can be removed such that both sidewalls of each spacer of said first generation can be used for forming a second generation of spacers.

After removal of the first generation of spacers, said second generation of spacers can be used as a mask for patterning fins in the layer underneath.

Similarly, another (third, fourth, etc.) generation of spacers can be formed using the sidewalls (each sidewall made available or only outer sidewalls of outer spacers) of the previous (respectively second, third, etc.) generation of spacers. And before using the last generation (n generation) of spacers as a mask for fins patterning, the previous generation (n−1 generation) of spacers is removed.

A method of the preferred embodiments presumes that the material used for the temporary pattern can be selectively removed with respect to the material used for the first and/or second generation(s) of spacers.

Likewise, the material used for a generation of spacers can be selectively removed with respect to the material used for the next generation.

A method of the preferred embodiments allows patterning multiple fins wherein the distance between two fins is defined by the thickness of the conformal layer deposited and etched back to form the spacers.

More particularly, the preferred embodiments provide a method for forming a mask on a layer to be patterned, in the manufacture of a semiconductor device, comprising the steps of: depositing over one or more temporary structure(s) made of a first material, a first conformal layer of a second material; removing said first conformal layer such as to form a first generation of spacers made of said second material; removing said temporary structure(s); depositing over said first generation of spacers a second conformal layer made of a third material; removing said second conformal layer such as to form a second generation of spacers made of said third material; and removing the first generation of spacers made of said second material.

A method according to the preferred embodiments can further comprise the steps of: depositing a third conformal layer made of said second material over said second generation of spacers; removing said third conformal layer such as to form a third generation of spacers made of said second material; and removing the second generation of spacers made of said third material.

In a method of the preferred embodiments wherein said third conformal layer is made of said second material, the step of removing said first generation of spacers is optional.

Alternatively, said third conformal layer can be made of a fourth material.

In a method according to the preferred embodiments, said temporary structure(s) can be (an) inlaid structure(s). Said temporary structure(s) is/are preferably freestanding structure(s). Said temporary structure(s) can be created using photolithography. Said temporary structure(s) can also be a previous generation of spacers.

Preferably, said layer underneath to be patterned (2) is a Silicon On Insulator (SOI) wafer.

In a method of the preferred embodiments, said first material can be silicon-dioxide, said second material silicon-nitride (SiₓN_{y}), and said third material silicon-dioxide.

Preferably, said first material is silicon-dioxide, said second material is silicon-nitride and said third material is SiON (silicon oxynitride).

Alternatively, in a method according to the preferred embodiments, said first material can be silicon-nitride, said second material silicon-dioxide, and said third material silicon-nitride.

Alternatively, said first material can be silicon or Germanium or Silicon-Germanium, said second material silicon-dioxide and said third material silicon-nitride.

In a method of the preferred embodiments, said nitride can be deposited by means of conformal chemical vapor deposition techniques such as LP-CVD (low-pressure CVD) and PE-CVD (plasma-enhanced CVD).

Said silicon-dioxide can be CVD deposited TEOS-oxide (using TetraEthylOrthoSilicate as a precursor).

In a method according to the preferred embodiments, said step of removing the temporary structure(s) (3) can be an etching process, more particularly a wet etching process.

In a method according to the preferred embodiments, said step of removing said generation of spacers can be an etching process, more particularly a wet etching process.

In a method according to the preferred embodiments, said conformal layer(s) can be etched back by means of reactive ion etching using a fluor comprising plasma.

A method according to the preferred embodiments can be used for the manufacture of a MugFET device, wherein said mask is used for patterning a plurality of fins in said underneath layer to be patterned (2).

In a method according to the preferred embodiments, said patterning for fins can be used in combination with a resist-based patterning of source/drain patterning.

Another object of the present preferred embodiments is a device (in particular a MuGFET device) obtainable by a method according to the preferred embodiments.

In a device according to the preferred embodiments, the distance between adjacent fins is preferably comprised between (about) 10 nm and (about) 80 nm; more preferably the distance between adjacent fins is (about) 20 nm.

In a device according to the preferred embodiments, the width of the fins is preferably comprised between (about) 10 nm and (about) 20 nm.

### BRIEF DESCRIPTION OF THE DRAWINGS

All drawings are intended to illustrate some aspects and preferred embodiments. Devices are depicted in a simplified way for reason of clarity. Not all alternatives and options are shown and therefore the preferred embodiments are not limited to the content of the given drawings. Like numerals are employed to reference like parts in the different figures.

FIGS. 1A through 11 are cross-sectional views illustrating the different processing steps for forming four dense fins (fin-quadrupling) according to a method of the preferred embodiments.

FIG. 2 shows a XSEM picture presenting the result after removal of the temporary pattern creating freestanding (nitride) spacers.

FIG. 3 shows XSEM pictures presenting the result after etching back the second conformal layer such that a second set of spacers (silicon-dioxide) 31 is created adjacent to the first set of spacers (nitride) 30. A contrast layer is deposited onto the spacers to make the difference between nitride and silicon-dioxide clearer.

FIG. 4 shows XSEM pictures presenting the result after applying the method of fin quadrupling creating four individual fins in the SOI layer.

FIGS. 5A through 5K are cross-sectional views illustrating the different processing steps for forming six dense fins (fin-sextupling) according to a method of the preferred embodiments.

FIGS. 6A through 6F illustrates the fin quadrupling processing (as described in the examples). FIG. 6A illustrates the sacrificial hardmask opening to form the temporary structure. FIG. 6B illustrates the sacrificial nitride spacer definition. FIG. 6C illustrates final spacer formation. FIG. 6D illustrates the sacrificial spacer removal (with use of a contrast layer). FIG. 6E illustrates the fin etch using the silicon-dioxide spacers as hardmask. FIG. 6F illustrates the fins after silicon-dioxide hardmask (spacers) removal.

### DETAILED DESCRIPTION OF THE PREFERRED EMBODIMENT

A method is disclosed for forming a mask structure upon a layer to define a pattern in said layer.

Said mask structure is formed by first depositing (or forming) a temporary structure onto said layer and forming vertical structures (also referred to in this application as spacers) (out of a deposited conformal layer) onto the sidewalls of said temporary structure.

Said temporary structure is then removed and spacer structures are formed onto the sidewalls of previously formed spacer structures.

By removing intermediate spacer structures, the distance between the remaining spacer structures is defined by the thickness of said deposited conformal layer.

The remaining spacer structures can then be used as a mask to define a dense pattern in the layer underneath.

The method of the preferred embodiments enables to pattern a high density of structures into a layer, said high density of structures further defined as structures which are very close to each other such that these structures can not be defined by classical photolithographic methods.

The distance between these structures is preferably from 10 nm up to 80 nm and more preferred from 20 nm to 40 nm.

The preferred embodiments provide a method to create multiple fins for use in a multiple gate structure. The distance between the individual fins is from 10 nm up to 80 nm and more preferred from 10 nm to 40 nm.

The width of said fins is preferably smaller than 20 nm.

The method is further characterized as a method for the patterning of a plurality of fins (i.e., more than two fins) in a finFET device whereby the distance between the individual fins is determined by spacer defined structures.

A spacer as referred to in this application is a vertical structure formed onto the sidewalls of a first structure (e.g. a temporary pattern).

After deposition of a layer of a suitable material over said first structure, an anisotropical removal (preferably etching) process is applied such that a vertical structure (a spacer) is obtained, said vertical structure further characterized as having a height at least equal or below the first structure and a width corresponding to the thickness of said deposited layer.

The patterning of fins using said spacer structures can be referred to as spacer defined patterning and is further characterized as a patterning wherein said spacers (as defined elsewhere herein) are used as hardmask structures to create a pattern in the layer underneath.

Preferably, a method of forming multiple fins according to the preferred embodiments comprises at least the steps of first creating a temporary pattern made of a first material.

Said temporary pattern can be a freestanding structure made of a first material using photolithography to define said temporary structure.

Alternatively and also preferred said temporary structure can be a trench-like structure (or in other words opening) made in a layer made of said first material, the width of said trench or opening can also be determined by photolithography.

Preferably said first material is a material commonly used in semiconductor processing as hardmask layer.

Onto (over) said temporary pattern a first conformal layer is deposited. Said first conformal layer is made of a second material.

Subsequently the first conformal layer is etched back (preferably by means of anisotropically etchback) such that a first set of spacers is formed onto the sidewalls of the temporary pattern.

The temporary pattern is then removed. The removal process can be a wet etching or a dry etching removal process depending on the material properties of said first material.

After removal of the temporary pattern two freestanding spacers structures are achieved, the distance between said spacers (also referred to as the first set of spacers) is determined by the width of the temporary structure, which is defined by photolithographic patterning.

Subsequently a second conformal layer made of a third material is uniformly deposited onto (over) the first set of spacers.

By anisotropically etching back said second conformal layer a second set of spacers is formed adjacent to the sidewalls of the first set of spacers.

The first set of spacers can then be removed such that four freestanding structures (spacers) made of said second material are obtained.

Said freestanding spacers can then be used as a mask to pattern fins in the layer underneath. As those freestanding spacers have been defined, an extra lithographic illumination (e.g., 193 nm lithography) can be used to define large pads that will act as the source and drain of the MuGFET device. This means that the active area etch (or in other words the patterning of the SOI layer to form fins and Source/Drain pads) consists of a combination of spacer defined patterning and resist based patterning. In another MuGFET device concept Source/Drain pads are omitted and the fins directly contacted at contact level.

The above-described method is referred to herein as “fin-quadrupling.”

The method described as “fin-quadrupling” can be further extended such that six freestanding structures are formed that can be used as a mask to pattern six individual fins in the layer underneath. Said method is referred to as “fin sextupling” herein.

After formation of the second set of spacers as described above, a third conformal layer is deposited onto (over) said first and second set of spacers. Said third conformal layer is preferably identical to said second material.

Alternatively, a fourth material can be chosen as third conformal layer.

The third conformal layer is anisotropically etched back to form a third set of spacers. Said third set of spacers are situated onto the outer sidewalls of said second set of spacers and are preferably made of identical material of said first set of spacers (for etch selectivity in further processing).

By removing the second set of spacers, (2 times) three free standing spacer structures made of preferably identical materials are achieved. The removal of the second set of spacers is preferably done by means of a wet or dry etching removal process.

The first and third set of spacers can then be used as a mask set (or hardmask structure) to define fins in the layer situated underneath the spacer structures. The patterning of the fins is preferably done by means of an anisotropically dry etching process (which is selective towards said hardmask structure).

After removal of the first and third set of spacers a final structure is obtained with multiple fins (here six individual fins or two set of three fins) wherein the distance between adjacent fins in one set of fins is determined by the thickness of the deposited conformal layers.

The following description and examples illustrate various preferred embodiments. It will be appreciated that there are numerous variations and modifications of these embodiments that are possible.

The preferred embodiments provide a method to create multiple fins for use in a multiple gate structure.

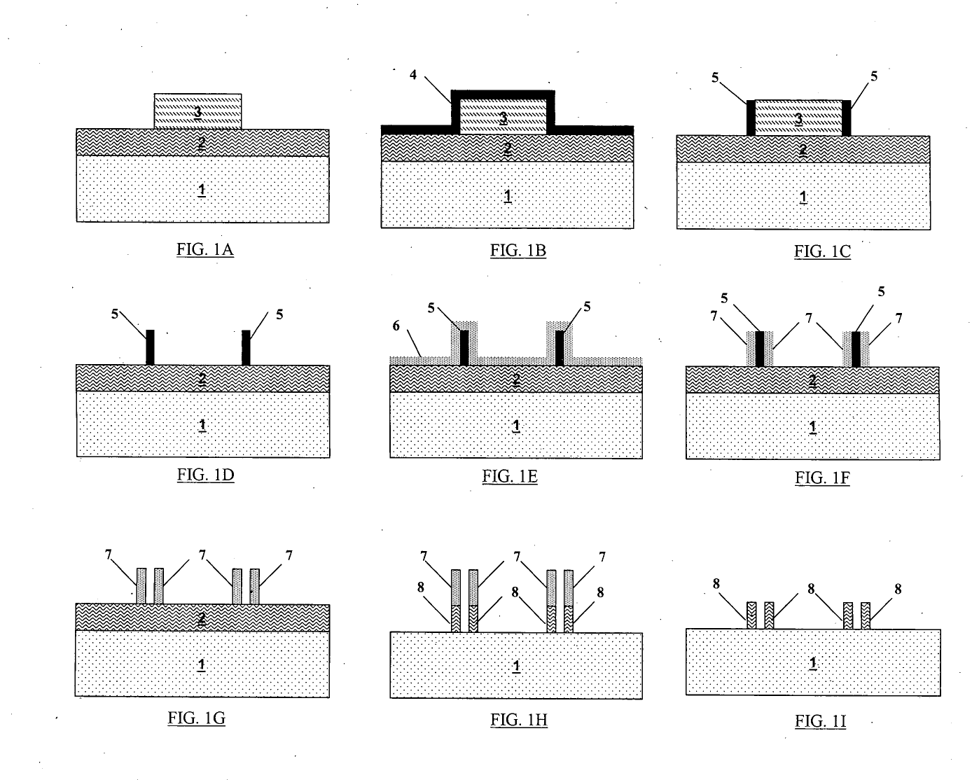

The method described in detail below is schematically shown in FIGS. 1A to 11 and FIGS. 5A-5K. It is further characterized as a method for the patterning of a plurality of fins in a multiple gate device (e.g. finFET) whereby the distance between individual fins is determined by spacer defined structures.

The method described below to form four individual fins is referred to as “fin quadrupling” because four fins are achieved starting from one temporary lithographic pattern.

The method can be further extended (including a repetition of steps) towards the formation of more individual fins (e.g. six) starting from one single temporary lithographic pattern. In the case six fins are formed, this method is referred to as “fin sextupling.”

The method of the preferred embodiments can be extended towards formation of higher number of fins (forming 8 fins and more) by repeating the steps of forming sacrificial and permanent spacers, including the removal of sacrificial spacers and the use of the permanent spacers as a hardmask structure to define fins in the layer underneath. The method can be extended as long as the permanent spacers are suitable for use as hardmask structures.

I. Method for “Fin Quadrupling”

Referring to FIG. 1A the method preferably starts from a substrate. When finFET processing, said substrate is preferably a Silicon On Insulator (SOI) wafer. More specifically, the top Si- or SOI-layer 2 is preferably p-type mono-crystalline and <100>-oriented and has typically a thickness of from 50 nm to 200 nm.

The buried oxide (BOX) layer 1, which is situated underneath the SOI layer, has typically a thickness of from 100 nm to 200 nm.

The bulk Si part of the substrate is preferably p-type mono-crystalline and <100>-oriented.

The method of forming multiple fins starts with the formation of a temporary pattern or structure 3 made of a first material onto the SOI-layer 2.

Suitable materials to be used as first material are commonly used hardmask materials. A preferred example of said first material can be silicon oxide, most preferred said silicon-dioxide is a TEOS-oxide (a SiO₂ film deposited by CVD using TetraEthylOrthoSilicate or Si(OC₂H₅)₄ as a precursor).

To create said temporary pattern, first a layer made of said first material (with preferred thickness of about 80 nm) is deposited onto the SOI layer followed by the deposition of photolithographic layers (not shown). Optical lithography (193 nm) is used to pattern the photosensitive layer(s).

The patterning of the temporary pattern in said first material is preferably done by means of reactive ion etching (also referred to as dry etching in this application) stopping on the SOI layer 2.

A fluor comprising plasma can be used for patterning said silicon-dioxide comprising layer such as TEOS-oxide, an example of such a plasma is a CF₄/CH₂F₂ comprising plasma (with bias power) obtaining a selectivity of 3:1 for Si:SiO₂.

FIG. 1A shows the final structure comprising the temporary pattern 3 obtained after patterning and after removal of remaining photosensitive material and residues by means of a strip process.

Subsequently a first conformal layer 4 made of a second material is deposited. An example of said second material can be a silicon-nitride layer, with general chemical formula SiₓN_{y} or more specific Si₃N₄. Said silicon-nitride layer is further referred to in this application as a “nitride” layer. Said nitride layer is preferably deposited by means of conformal deposition techniques such as Low-Pressure Chemical Vapor Deposition (LP-CVD), Plasma-Enhanced Chemical Vapor Deposition (PE-CVD), and the like.

By means of reactive ion etching said first conformal layer 4 is etched back stopping on the temporary structure 3, resulting in a first set of spacers 5 situated at the sidewalls of the temporary pattern 3.

Sufficient etch selectivity is required with respect to the SOI-layer 2.

When the second material is a nitride layer, the etchback can be performed using, e.g., a CH₃F/CF₄/O₂ plasma (with bias power) obtaining a selectivity of about 15:1 for both silicon-dioxide and Si compared to nitride.

If residues remain after etchback, a sulfuric peroxide mixture and an ammonia peroxide mixture can be used to remove the residual etch products.

The temporary pattern 3 is then removed. Said removal process is preferably a wet etching process which is selective to both the first set of (nitride) spacers 5 as to the SOI-layer 2.

When the temporary pattern is made of silicon-dioxide such as TEOS-oxide, the wet etching can be done in a diluted HF solution (e.g. 2.5 min. in 2% HF).

After removal of the temporary pattern 3 two freestanding spacer structures 5 are achieved, the distance between said spacers (also referred to as the first set of spacers) is determined by the width of the temporary structure, which is defined by photolithographic patterning.

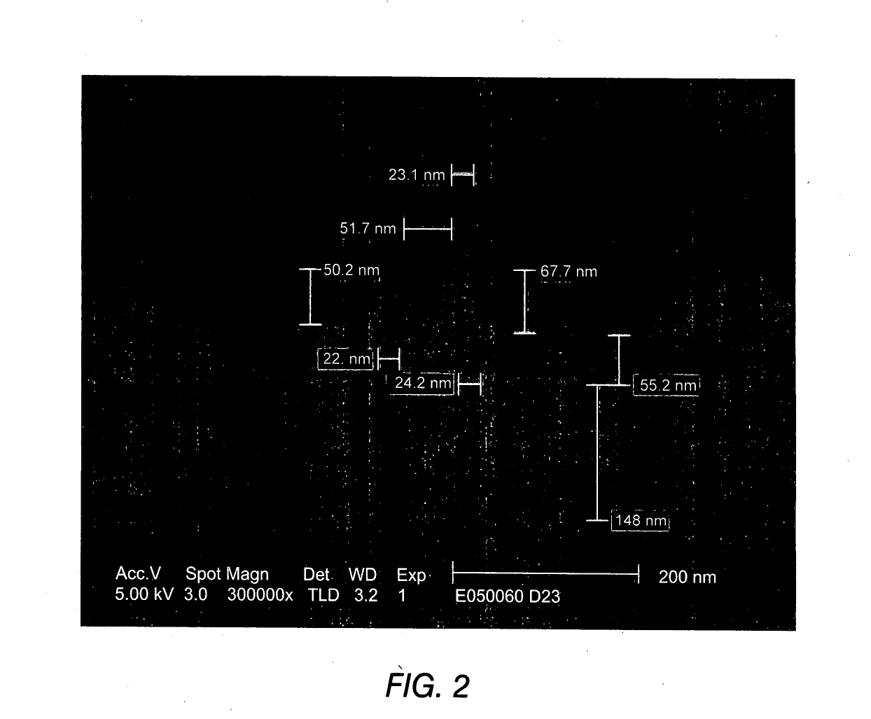

FIG. 1D schematically shows the resulting structure after removal of the temporary pattern 3 and FIG. 2 shows an XSEM image illustrating the freestanding (nitride) spacers 5.

Subsequently a second conformal layer 6 made of a third material is conformally deposited onto the first set of spacers 5 as schematically shown in FIG. 1E.

A silicon-dioxide (such as SiO₂) layer, such as TEOS-oxide, can be used as the third material (e.g., with aimed thickness of about 30 nm). The thickness of said deposited layer will determine the width of the fins obtained in the layer underneath. The minimal thickness of the fin that can be achieved is further dependent on the aspect ratio A (meaning the proportional relationship of the height h of the fin to the width w of the fin or A=h_{fin}/w_{fin}). A too high aspect ratio needs to be avoided with respect to line collapse.

The second conformal layer 6 is then etched back using the SOI layer 2 as stopping layer.

A plasma comprising CF₄/CH₂F₂ can be used to perform this anisotropically etching of TEOS-oxide.

The result is a second set of spacers 7 situated adjacent to or next to the first set of (nitride) spacers 5.

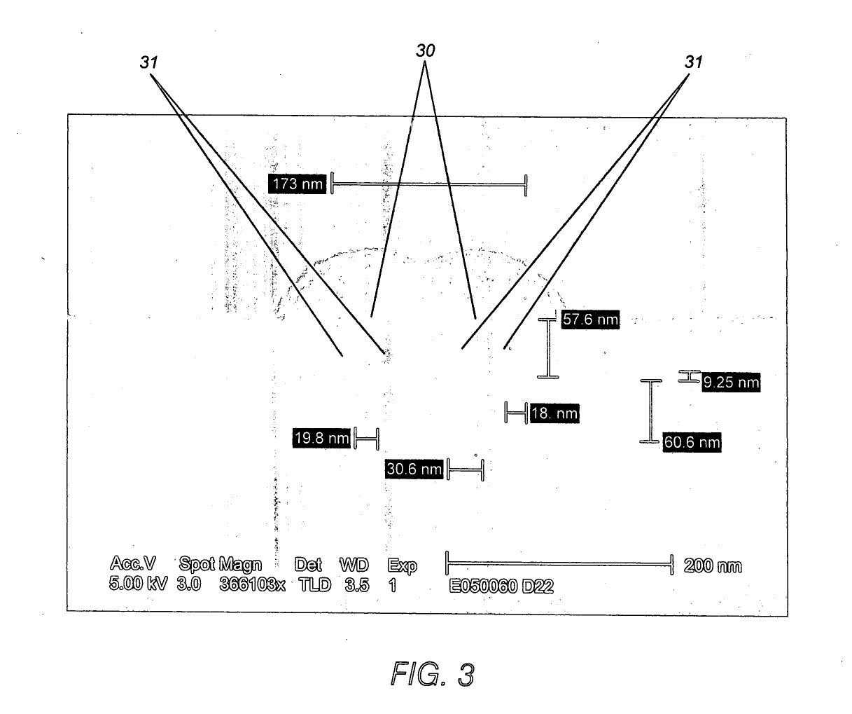

FIG. 3 shows a XSEM photo illustrating the first 30 and second 31 set of spacers.

FIG. 1F gives a schematically view on the obtained structure so far.

When “fin quadrupling”, the first set 5 of spacers is then removed such that the second set of spacers 7 can be used as mask (also referred to as hardmask structure) to define multiple (four) fins 8 in de SOI layer underneath.

A CH₃/CF₄/O₂ comprising plasma can be used to remove the first set of spacers 5 and a HBr/Cl₂/O₂/CF₄ comprising plasma can be used to etch the fins 8 in the SOI layer 2 using spacers 7 as a mask.

The structure (after fin patterning) is shown schematically in FIG. 1H, the final structure after removal of the second set of (silicon-dioxide) spacers 7 is shown in FIG. 1I.

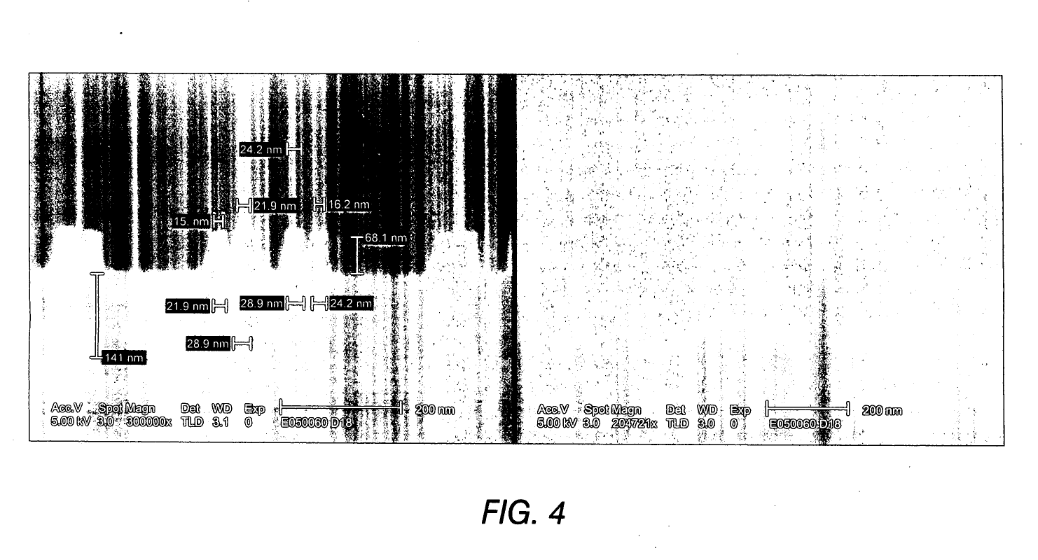

FIG. 4 is a XSEM picture illustrating the fin quadrupling or in other words forming two sets of fins whereby the distance between the individual fins in each set of fins is defined by the thickness of the deposited conformal layer(s) and whereby the distance between the two sets of fins is defined by lithography.

A multiple fin structure is thus obtained with a very small distance in between the fins (creating a high fin density).

As an alternative and also preferred, the first material to be used to define the temporary pattern 3 can be silicon-dioxide (e.g. TEOS-oxide), the second material to be used to create the first set of spacers 5 can be nitride and the third material to be used to create the second set of spacers 7 can be SiON.

In another alternative, the first material to be used to define the temporary pattern 3 can be nitride, the second material to be used to create the first set of spacers 5 can be silicon-dioxide (e.g., TEOS-oxide), and the third material to be used to create the second set of spacers 7 can be nitride.

In still another alternative, the first material to be used to define the temporary pattern 3 can be silicon (Si) or Germanium (Ge) or Silicon-Germanium (Siₓ/Ge_{y} e.g. x=70, y=30), the second material to be used to create the first set of spacers 5 can be silicon-dioxide (e.g. TEOS-oxide) and the third material to be used to create the second set of spacers 7 can be nitride. In this case there is a need to deposit an extra stopping layer onto the SOI layer 2 to avoid/limit SOI recess during the patterning of the temporary pattern 3.

II. Method for “Fin Sextupling”

The method as described in previous part can be extended towards the formation of six individual fins, all spacer-defined and very close to each other starting from one lithographic (temporary) pattern.

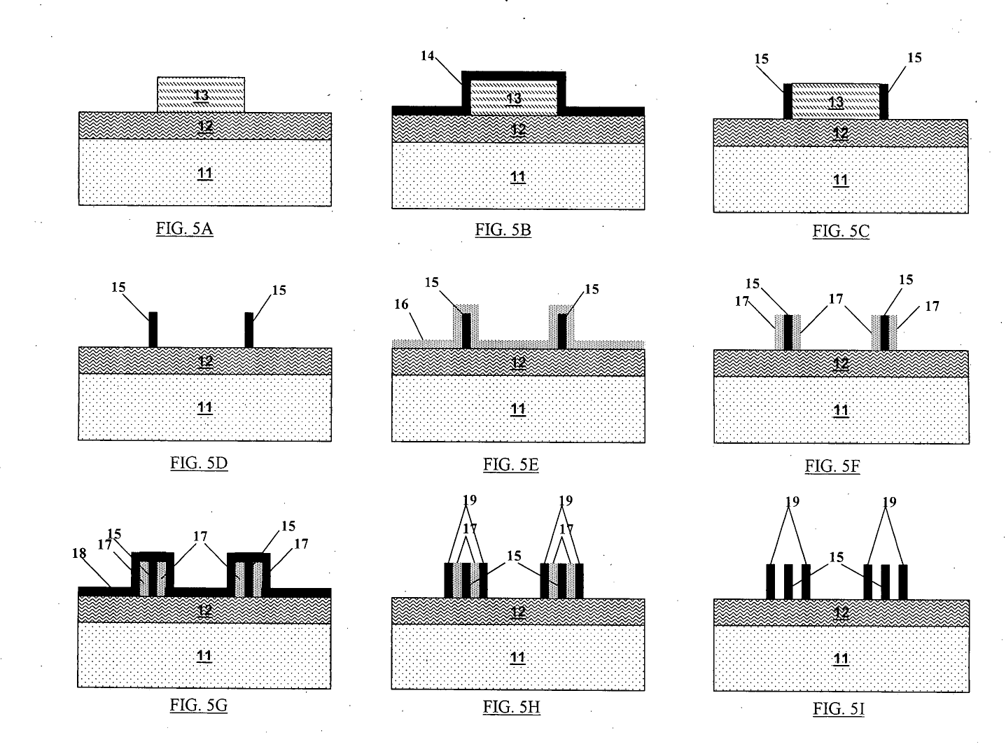

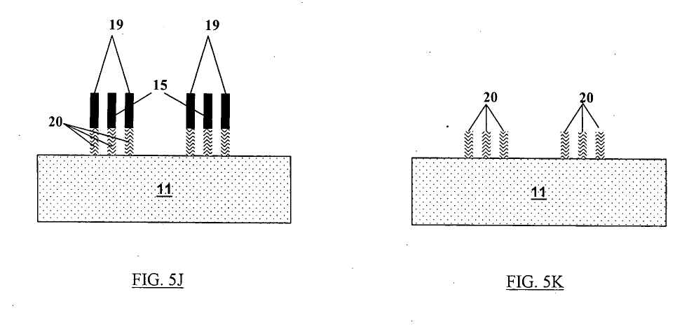

The method, referred to as “fin sextupling” is schematically shown in FIGS. 5A to 5K and described in detail below.

Referring to FIG. 5A the method preferably starts from a Silicon On Insulator (SOI) wafer. More specifically, the top Si- or SOI-layer 12 is preferably p-type mono-crystalline and <100>-oriented and has typically a thickness from 50 nm to 200 nm.

The buried oxide (BOX) layer 11, which is situated underneath the SOI layer, has typically a thickness from 100 nm to 200 nm.

The bulk Si part of the substrate is preferably p-type mono-crystalline and <100>-oriented.

The method of forming multiple (six) fins starts with the formation of a temporary pattern or structure 13 made of a first material onto the SOI-layer 12.

Suitable materials to be used as first material are commonly used hardmask materials such as TEOS-oxide, Plasma-Enhanced Chemically Vapor Deposition (PE-CVD) deposited silicon-dioxide, thermally grown SiO₂, etc

First a layer made of said first material is deposited onto the SOI layer 12 (with preferred thickness of about 80 nm) followed by the deposition of standard photolithographic layers (not shown).

Optical lithography (193 nm) is used to pattern the photosensitive layer(s).

The patterning of temporary pattern (structure) 13 is preferably done by means of reactive ion etching (also referred to as dry etching in this application) stopping on the SOI layer 12.

A fluor comprising plasma can be used when the first material is silicon-dioxide (TEOS-oxide), an example of such a plasma is a CF₄/CH₂F₂ plasma (with bias power) obtaining a selectivity of 3:1 for Si:SiO₂.

FIG. 5A shows the final structure comprising the temporary pattern 13 after removal of remaining photosensitive material and residues by means of a strip process.

Subsequently a first conformal layer 14 made of a second material is deposited (FIG. 5B). An example of said second material can be a silicon-nitride layer, with general chemical formula SiₓN_{y} or more specific Si₃N₄. Said silicon-nitride layer is further referred to in this application as a “nitride” layer. Said nitride layer is preferably deposited by means of conformal deposition techniques such as Low-Pressure Chemical Vapor Deposition (LP-CVD), Plasma-Enhanced Chemical Vapor Deposition (PE-CVD), etc. The thickness of said deposited nitride layer is minimum 5 nm; said thickness will determine the width of the fins obtained in the layer underneath. The minimal thickness of the fin that can be achieved is further dependent on the aspect ratio A (meaning the proportional relationship of the height h of the fin to the width w of the fin or A=h_{fin}/w_{fin}). A too high aspect ratio needs to be avoided with respect to line collapse.

By means of reactive ion etching said first conformal layer 14 is etched back stopping on the temporary structure 13, resulting in a first set of spacers 15 situated at the sidewalls of the temporary pattern 13 (FIG. 5C).

Sufficient etch selectivity is required with respect to the SOI-layer 12.

When the second material is a nitride layer, the etchback can be performed using e.g. a CH₃F/CF₄/O₂ plasma (with bias power) obtaining a selectivity of about 15:1 for both oxide and Si compared to nitride.

If residues remain after etchback, a sulfuric peroxide mixture and an ammonia peroxide mixture can be used to remove the residual etch products.

The temporary pattern 13 is then removed; said removal process is preferably a wet etching process which is selective to both the first set of (nitride) spacers 5 as to the SOI-layer 12.

When the second material (used to define the first set of spacers) is nitride, this wet etching process can be done in a diluted HF solution (e.g. 2.5 min. in 2% HF).

After removal of the temporary pattern 12 two freestanding spacer structures 15 are achieved, the distance between said spacers (also referred to as the first set of spacers) is determined by the width of the temporary structure, which is defined by photolithographic patterning.

FIG. 5D schematically shows the resulting structure after removal of the temporary pattern 15.

Subsequently a second conformal layer 16 made of a third material is uniformly deposited onto the first set of spacers 15 as schematically shown in FIG. 5E.

A Silicon-dioxide layer such as TEOS-oxide can be used as third material (e.g., with aimed thickness of about 30 nm).

The second conformal layer 16 is then etched back using the SOI layer 12 as stopping layer; a plasma comprising CF₄/CH₂F₂ can be used to perform the anisotropically etching when the third material is silicon-dioxide (e.g. TEOS-oxide). This finally results in a second set of spacers 17 situated adjacent to or next to the first set of (nitride) spacers 15 (FIG. 5F).

After formation of the second set of spacers 17, a third conformal layer 18 is deposited onto said first and second set of spacers.

Said third conformal layer 18 is preferably made of said second material (or in other words identical to the first conformal layer 14). Alternatively a fourth material can be used as third conformal layer as long as the etch selectivity is comparable to the second material.

An example of said second material can be a nitride layer deposited by means of LP-CVD.

By means of reactive ion etching said third conformal layer 18 is etched back stopping on the SOI layer 12, resulting in a third set of spacers 19 situated onto the outer sidewalls of said second set of spacers 17 and made of similar material of said first set of spacers 15.

By removing the second set of spacers (silicon-dioxide), three free standing spacer structures made of similar material (e.g. nitride) are achieved.

The removal of the second set of spacers is preferably done by means of a wet removal process (e.g., a wet removal in 2% HF when TEOS-oxide spacers are used).

The first 15 and third 19 set of spacers can then be used as a mask set to define fins 20 in the layer situated underneath the spacer structures (in SOI layer 12).

The patterning of the fins 20 is preferably done by means of an anisotropically dry etching process.

After removal of the first 15 and third 19 set of spacers a final structure is obtained with multiple fins 20 (here three) wherein the distance between adjacent fins 20 is determined by the thickness of the deposited conformal layers 14, 16, 18.

When the first 15 and third 17 set of spacers is made of nitride a wet removal process in H₃PO₃ can be applied.

As an alternative and also preferred, the first material to be used to define the temporary pattern 13 can be silicon-dioxide (e.g. TEOS-oxide), the second material to be used to create the first and third set of spacers 15, 19 can be nitride and the third material to be used to create the second set of spacers 17 can be SiON.

In another alternative, the first material to be used to define the temporary pattern 13 can be nitride, the second material to be used to create the first and third set of spacers 15, 19 can be silicon-dioxide (e.g., TEOS-oxide), and the third material to be used to create the second set of spacers 17 can be nitride.

In still another alternative, the first material to be used to define the temporary pattern 13 can be silicon (Si) or Germanium (Ge) or Silicon-Germanium (Siₓ/Ge_{y} e.g., x=70, y=30), the second material to be used to create the first and third set of spacers 15, 19 can be silicon-dioxide (e.g. TEOS-oxide) and the third material to be used to create the second set of spacers 17 can be silicon-nitride. When using SiGe or Ge, said silicon-nitride layer is preferably deposited with a lower thermal budget, an example could be Si₃N₄gen™, a silicon-nitride layer deposited by a high-temperature CVD system from Applied Materials, the so called the SiNgen™ Centura. This system operates at a lower deposition temperature than conventional methods to minimize the amount of time the wafer is exposed to high temperatures. When a silicon (Si), Germanium (Ge) or Silicon-Germanium is used as temporary pattern, an extra stopping layer (e.g. 4 nm thermally grown oxide) is deposited onto the SOI layer 2 to avoid/limit SOI recess during the patterning of the temporary pattern 13.

It must be clear that combinations of the above described methods referred to as “fin quadrupling” and “fin sextupling” are also part of the preferred embodiments.

The combination of depositing a conformal layer and spacer defined patterning of said conformal layer can be repeated and altered such that very high density of fins can be achieved.

### EXAMPLES

### Example 1

Fin Quadrupling Processing

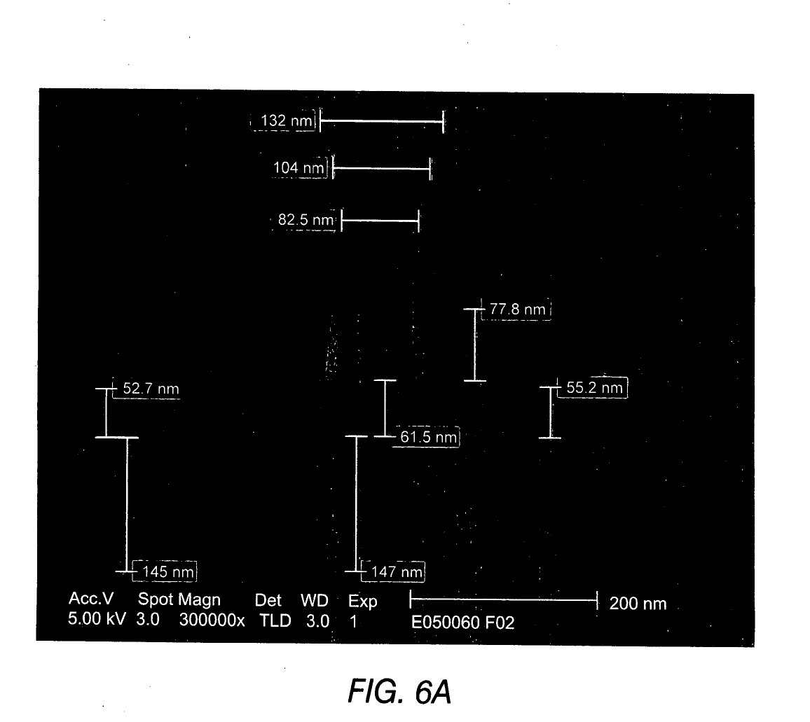

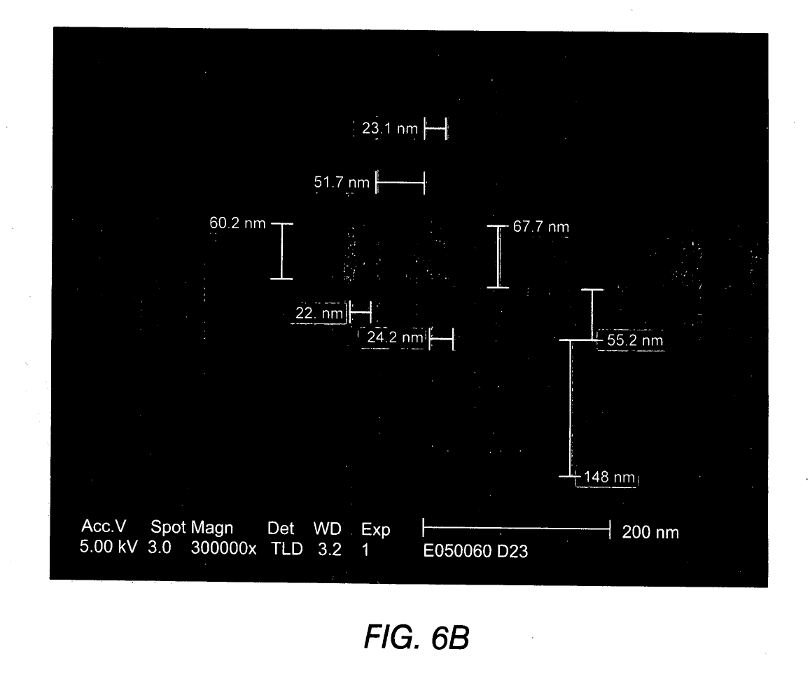

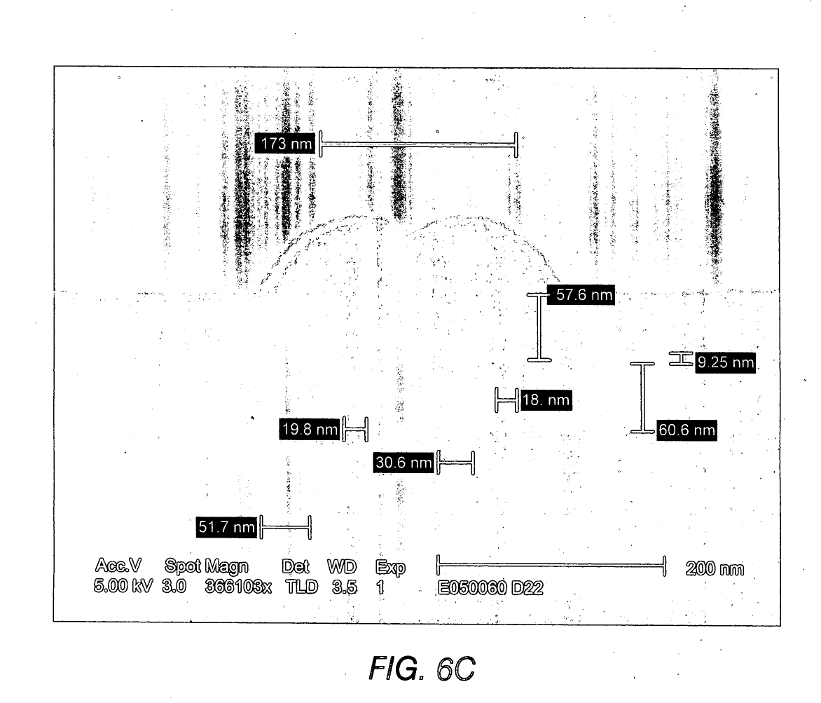

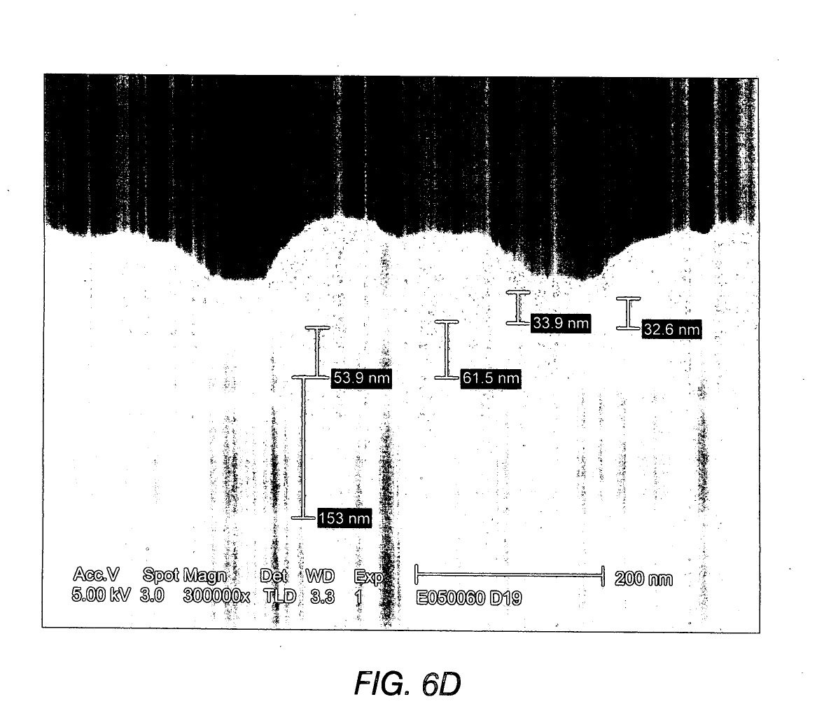

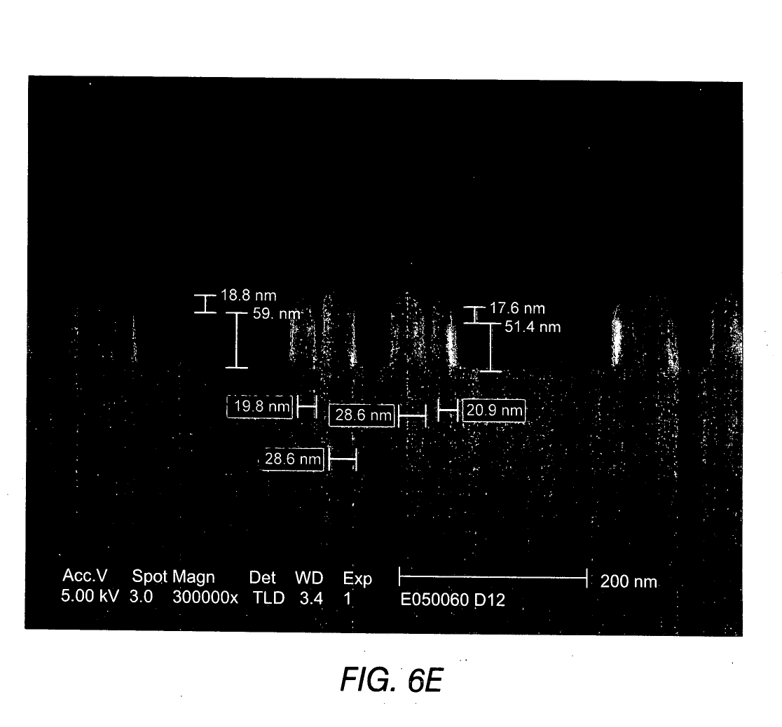

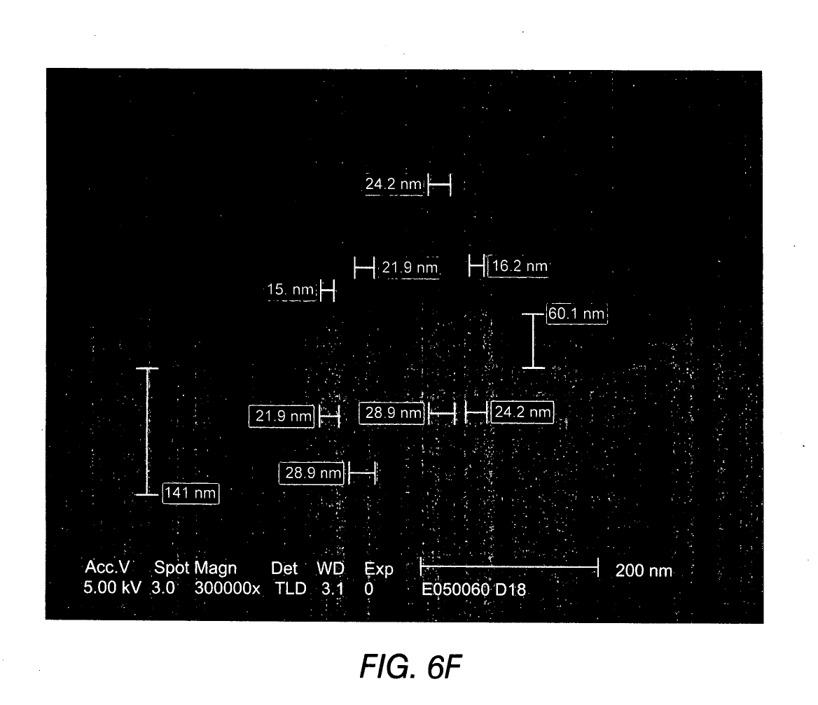

The experiment starts from a stack comprising the following layers: 65 nm Si/60 nm TEOS-oxide/77 nm BARC/230 nm resist (193 nm). The different process steps are illustrated in FIGS. 6A to 6F.

Optical lithography (193 nm) is used to pattern a sacrificial hardmask (HM), said sacrificial HM (also referred to in this application as a temporary structure) is made of TEOS-oxide. The BARC layer and the sacrificial HM are opened stopping on the SOI layer (see FIG. 6A).

Subsequently 30 nm of LP-CVD (Low-Pressure Chemical Vapor Deposition) nitride is deposited on top of the pattern defined by the sacrificial hardmask structure. Consequently a spacer is formed on the sidewalls of the sacrificial hardmask structure. After spacer etch, the wafer is exposed subsequently to a sulfuric peroxide mixture and an ammonia peroxide mixture to remove residual etch products.

In the next process step, the sacrificial HM structure is removed selectively to both the sacrificial nitride spacer as the SOI-layer. This was done in a 2% HF solution (2.5 min). This is illustrated in FIG. 6B.

As the sacrificial nitride spacers have been defined and the sacrificial HM structure is removed, a TEOS-oxide film of 30 nm is deposited. The source/drain pads are defined with conventional lithography (193 nm). Consequently, the oxide layer is removed anisotropically resulting in a second generation of spacers (silicon-dioxide spacers) next to the sacrificial nitride spacers (shown in FIG. 6C). Selectivity to the SOI-layer is desired.

A CH₃F/CF₄/O₂ comprising plasma is used for dry removal of the sacrificial nitride spacers (shown in FIG. 6D with use of a contrast layer). Said CH₃F/CF₄/O₂ comprising plasma is selective to both silicon-dioxide and Si resulting in a silicon-dioxide HM (made of silicon-dioxide spacers) on top of an SOI-layer with limited recess.

After definition of the hardmask pattern for fins (made of previously formed silicon-dioxide spacers), source and drain, finally the SOI-layer is patterned. In FIG. 6E an XSEM image of fins is shown after patterning: 4 separate fins have been etched into the SOI layer starting from one sacrificial silicon-dioxide line (FIG. 6A). This clearly demonstrates the concept of fin quadrupling (the slope of the profile of the sacrificial HM can be further improved which will avoid CD difference between middle and outer fins). The distance between the middle fins corresponds to the line width of the sacrificial HM or temporary structure (FIG. 6A) whereas the distance between the two outer fins is determined by the width of the sacrificial nitride spacer (FIG. 6B). An XSEM image after silicon-dioxide HM is removal (2% HF solution, 30 s) is shown in FIG. 6F. The outer fins are less high compared to the inner fins due to the recess in the SOI layer caused by the sacrificial HM opening (FIG. 6A) followed by the sacrificial nitride spacer etch (FIG. 6B).

All references cited herein, including but not limited to published and unpublished applications, patents, and literature reference, are incorporated herein by reference in their entirety and are hereby made a part of this specification. To the extent publications and patents or patent applications incorporated by reference contradict the disclosure contained in the specification, the specification is intended to supersede and/or take precedence over any such contradictory material.

The term “comprising” as used herein is synonymous with “including,” “containing,” or “characterized by,” and is inclusive or open-ended and does not exclude additional, unrecited elements or method steps.

All numbers expressing quantities of ingredients, reaction conditions, and so forth used in the specification are to be understood as being modified in all instances by the term “about.” Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

The above description discloses several methods and materials of the present invention. This invention is susceptible to modifications in the methods and materials, as well as alterations in the fabrication methods and equipment. Such modifications will become apparent to those skilled in the art from a consideration of this disclosure or practice of the invention disclosed herein. Consequently, it is not intended that this invention be limited to the specific embodiments disclosed herein, but that it cover all modifications and alternatives coming within the true scope and spirit of the invention.

What is claimed is:

1. A method for forming a mask on a layer to be patterned for the manufacture of a multiple fin structure in a multi-gate device, the method comprising:
depositing, over at least one temporary structure comprising a first material, a first conformal layer comprising a second material;
removing the first conformal layer so as to form a first generation of spacers comprising the second material;
removing the temporary structure;
depositing over the first generation of spacers a second conformal layer comprising a third material;
removing the second conformal layer so as to form a second generation of spacers comprising the third material; and
removing the first generation of spacers comprising the second material, whereby a mask is formed.

2. The method according to claim 1, further comprising:
depositing a third conformal layer comprising the second material over the second generation of spacers;
removing the third conformal layer so as to form a third generation of spacers comprising the second material; and
removing the second generation of spacers comprising the third material.

3. The method according to claim 1, further comprising:
depositing a third conformal layer comprising a fourth material over the second generation of spacers;
removing the third conformal layer such as to form a third generation of spacers comprising fourth material; and
removing the second generation of spacers comprising the third material.

4. The method according to claim 2, wherein the step of removing the first generation of spacers comprising the second material is not conducted.

5. The method according to claim 1, wherein the temporary structure is a freestanding structure.

6. The method according to claim 1, wherein the temporary structure is an inlaid structure.

7. The method according to claim 1, wherein the temporary structure is created using photolithography.

8. The method according to claim 1, wherein the temporary structure comprises a previous generation of spacers.

9. The method according to claim 1, wherein the layer to be patterned is a silicon on insulator wafer.

10. The method according to claim 1, wherein the first material is silicon-dioxide, the second material is silicon nitride, and the third material is silicon dioxide.

11. The method according to claim 1, wherein the first material is silicon dioxide, the second material is silicon nitride, and the third material is silicon oxynitride.

12. The method according to claim 1, wherein the first material is silicon nitride, the second material is silicon dioxide, and the third material is silicon nitride.

13. The method according to claim 1, wherein the first material is selected from the group consisting of silicon, germanium, and silicon-germanium; wherein the second material is silicon dioxide; and wherein the third material is silicon nitride.

14. The method according to claim 1, wherein at least one of the first material, the second material, and the third material is a nitride; and wherein the nitride is deposited by a conformal chemical vapor deposition technique selected from the group consisting of low-pressure chemical vapor deposition and plasma-enhanced chemical vapor deposition.

15. The method according to claim 1, wherein at least one of the first material, the second material, and the third material is a silicon dioxide; and wherein the silicon dioxide is chemical vapor deposition deposited tetraethylorthosilicate-oxide.

16. The method according to claim 1, wherein removing the temporary structure is accomplished by an etching process.

17. The method according to claim 16, wherein the etching process is a wet etching process.

18. The method according to claim 1, wherein removing the first generation of spacers is accomplished by an etching process.

19. The method according to claim 18, wherein the etching process is a wet etching process.

20. The method according to claim 1, wherein at least one of the first conformal layer and the second conformal layer is etched back by reactive ion etching using a fluor-comprising plasma.

21. Use of a method according to claim 1 for the manufacture of a multi-gate field effect transmitter device, wherein the mask is used for patterning a plurality of fins in the layer to be patterned.

22. Use of a method according to claim 1, wherein patterning for a multiple fin structure is used in combination with a resist-based patterning of a source/drain patterning.

23. A device obtainable by a method according to claim 21.

24. A device obtainable by a method according to claim 22.

25. A device according to claim 23, wherein a distance between adjacent fins is from about 10 nm to about 80 nm.

26. A device according to claim 23, wherein a distance between adjacent fins is about 20 nm.

27. A device according to claim 23, wherein a width of a fin is from about 10 nm to about 20 nm.
